(19) United States
(12) Patent Application Publication
(10) Pub. No.: US 2026/0063735 A1
(43) Pub. Date: Mar. 5, 2026

(54) RING SHAPED TMR ELEMENTS PROVIDING INCREASED LINEARITY

(71) Applicant: Allegro MicroSystems, LLC, Manchester, NH (US)

(72) Inventors: Noémie Belin, Villejuif (FR); Paolo Campiglio, Arcueil (FR); Maxime Rioult, Massy (FR); Pierrick Charlier, Palaiseau (FR)

(73) Assignee: Allegro MicroSystems, LLC, Manchester, NH (US)

(21) Appl. No.: 18/817,473

(22) Filed: Aug. 28, 2024

(51) Int. Cl. G01R 33/09; G01R 33/00

(52) U.S. Cl. CPC G01R 33/098; G01R 33/0005; G01R 33/0052

(57) ABSTRACT

Systems, circuits, and methods provide ring shaped TMR elements having increased linearity. Such ring shaped TMR elements provide transducer output responses to changes in input magnetic field levels that are more linear compared to prior TMR techniques and devices. In some embodiments, a free layer having a ring shape can create a circular magnetization resulting in a TMR element linearity that can be adjusted depending on the width of the ring shaped element. In some embodiments, such ring shaped TMR elements can overcome small diameter fabrication limits of prior art vortex elements.

### BACKGROUND

Magnetic field sensors are often used to detect a ferromagnetic target. They often act as sensors to detect motion or position of the target. Such sensors are ubiquitous in many areas of technology including robotics, automotive, manufacturing, etc. For example, a magnetic field sensor may be used to detect when a vehicle's wheel locks up, triggering the vehicle's control processor to engage the anti-lock braking system. In this example, the magnetic field sensor may detect rotation of the wheel. Magnetic field sensors may also detect distance between the magnetic field sensor and an object. Sensors such as these may be used to detect the proximity of the object as it moves toward and away from the magnetic field sensor.

Hall effect elements are one class of magnetic field sensing elements that have a variable voltage in response to changes in an applied or sensed magnetic field. Magnetoresistance elements are another class of magnetic sensing elements that have a variable resistance that changes in response to changes in an applied or sensed magnetic field. There are different types of magnetoresistance elements, for example, semiconductor magnetoresistance elements such as ones including Indium Antimonide (InSb), anisotropic magnetoresistance (AMR) elements, giant magnetoresistance (GMR) elements, and tunneling magnetoresistance (TMR) elements, which are also referred to as magnetic tunnel junction (MTJ) elements in reference to the included MTJ. Some magnetoresistance elements, e.g., GMR and TMR elements, may have a limited linear output range in which a change in sensed magnetic field intensity is linear with a corresponding change in the resistance of the elements.

Conventional tunneling magnetoresistive (TMR)-based sensors use TMR elements arranged in a bridge configuration. TMR elements typically have a relatively narrow linearity range and their linearity may be further compromised as the width of the devices is decreased.

### SUMMARY

Aspects of the present disclosure are directed to and include systems, devices, circuits, and methods providing ring shaped TMR elements with improved linearity.

One general aspect of the present disclosure includes a tunneling magnetoresistance (TMR) sensor. The TMR sensor can include: a plurality of magnetic tunneling junction (MTJ) ring structures having a bridge configuration and configured to provide a bridge output signal; where each MTJ ring structure includes a stack including a free layer, a barrier layer, and a fixed layer have a fixed magnetic orientation, where each MTJ ring structure is configured to provide an output signal indicative of a magnetic field aligned with the fixed magnetic orientation, and where each MTJ ring structure has a ring shape defining an aperture; and output circuitry configured to receive the bridge output signal and provide signal conditioning of the output signal.

Implementations may include one or more of the following features. The bridge configuration of the TMR sensor may include a Wheatstone bridge. The bridge configuration may include a half-bridge. A width of each MTJ ring structure can be between about 1.0 micron and about 2.0 microns, in some embodiments. A radial thickness of each MTJ ring structure may be between about 150 nm and about 500 nm, in some embodiments. The ring shape may include a plurality of rings overlapping at one or more overlap regions. The plurality of rings may include two rings. The ring shape may include non-circular shapes such as ellipses, ovals, rounded rectangles or other polygons, etc. The free layer may include cobalt-iron-boron. The fixed layer may include cobalt-iron or cobalt-iron-boron. The TMR sensor can be configured as a differential sensor. The TMR sensor can be configured as an angle sensor. Implementations of the described techniques may include hardware, a method or process, or computer software on a computer-accessible medium, e.g., configured and arranged to calculate/determine a differential voltage, an angle, etc.

Another general aspect of the present disclosure includes a magnetic tunneling junction (MTJ) ring element. The magnetic tunneling junction can include: a free layer of ferromagnetic material; a barrier layer disposed adjacent the free layer; a fixed layer of ferromagnetic material disposed adjacent the barrier layer and having a fixed magnetic orientation; a first conductive element connected to the free layer; and a second conductive element connected to the fixed layer; where the MTJ ring element is configured to produce an output signal indicative of a presence of a magnetic field aligned fixed magnetic orientation of the fixed layer, and where the MTJ ring element is configured as a ring shape defining an aperture.

Implementations may include one or more of the following features. A width of the MTJ ring element may be between about 1.0 micron and about 2.0 microns, in some embodiments. A radial thickness of the MTJ ring element may be between about 150 nm and about 500 nm, in some embodiments. The ring shape may include a plurality of rings overlapping at one or more overlap regions. The plurality of rings may include two rings. The free layer may include cobalt-iron-boron. The fixed layer may include cobalt-iron or cobalt-iron-boron.

A further general aspect of the present disclosure includes a method of making a TMR sensor having ring elements. The method can include: providing a plurality of magnetic tunneling junction (MTJ) ring structures having a bridge configuration; where each MTJ ring structure includes a stack including a free layer, a barrier layer, and a fixed layer have a fixed magnetic orientation, where each MTJ ring structure is configured to provide an output signal indicative of a magnetic field aligned with the fixed magnetic orientation, and where each MTJ ring structure has a ring shape defining an aperture; and providing output circuitry configured to receive the output signal and provide signal conditioning of the output signal. Other embodiments of the aspect include corresponding computer systems, apparatus, and computer programs recorded on one or more computer storage devices, each configured to perform the actions of the methods.

Implementations may include one or more of the following features. The barrier layer may include an oxide. The oxide may include aluminum oxide or magnesium oxide. The free layer may include cobalt-iron-boron. The fixed layer may include cobalt-iron or cobalt-iron-boron. A width of each MTJ ring structure may be between about 1.0 micron and about 2.0 microns, in some embodiments. A radial thickness of each MTJ ring structure may be between about 150 nm and about 500 nm, in some embodiments. The ring shape of each MTJ ring structure may include a plurality of rings overlapping at one or more overlap (overlapping) regions. The plurality of rings may include two rings.

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the present disclosure, which is susceptible of many embodiments. What follows is illustrative, but not exhaustive, of the scope of the present disclosure.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principals of the concepts described herein. Furthermore, embodiments are illustrated by way of example and not limitation in the figures, in which:

FIG. 1 is a diagram showing magnetization of the free layer of an example prior art disc shaped TMR element;

FIG. 2 shows an example ring shaped TMR element, in accordance with the present disclosure;

FIGS. 3A-3C are diagrams showing linearity vs. field strength and magnetizations for two different field strengths, respectively, for an example ring shaped TMR element, in accordance with the present disclosure;

FIG. 4 is a diagram showing magnetization for an example double-ring shaped TMR element, in accordance with the present disclosure;

FIGS. 5A-5B are graphs showing comparisons of magnetization of an example ring shaped TMR element in accordance with the present disclosure and a prior art disc shaped TMR element shown in FIGS. 5C-5D, respectively;

FIGS. 6A-6B show a circuit diagram for an example TMR sensor utilizing ring shaped TMR elements, in accordance with the present disclosure;

FIG. 7 shows steps in an example method of making ring shaped TMR elements, in accordance with the present disclosure; and

FIG. 8 is a block diagram of an example computer system operative to perform processing, in accordance with the present disclosure.

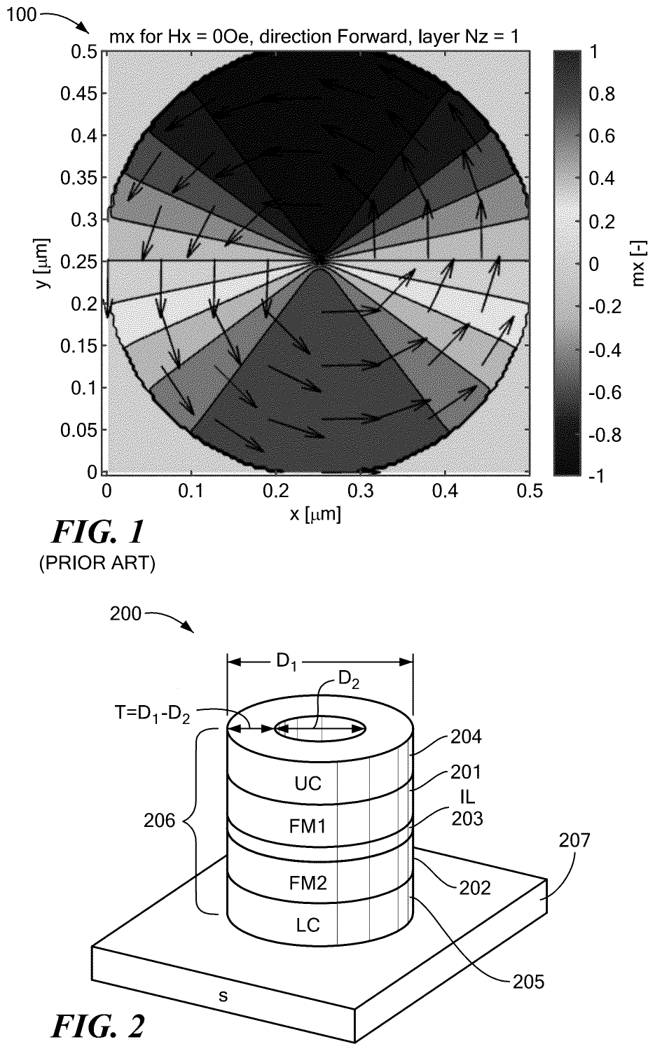

### DETAILED DESCRIPTION

The features and advantages described herein are not all-inclusive; many additional features and advantages will be apparent to one of ordinary skill in the art in view of the drawings, specification, and claims. Moreover, it should be noted that the language used in the specification has been selected principally for readability and instructional purposes, and not to limit in any way the scope of the inventive subject matter. The subject technology is susceptible of many embodiments. What follows is illustrative, but not exhaustive, of the scope of the subject technology.

Aspects of the present disclosure are directed to and include systems, circuits, and methods providing ring shaped (a.k.a., “donut” shaped) TMR elements with improved linearity. Such ring shaped TMR elements provide transducer output responses to changes in input magnetic field levels that are more linear compared to prior TMR techniques and devices. In some embodiments, a free layer having a ring shape can create a circular magnetization resulting in a TMR element linearity that can be adjusted depending on the width of the ring shaped element. In some embodiments, such ring shaped TMR elements can overcome small diameter fabrication limits of prior art vortex elements.

FIG. 2 shows an example ring shaped TMR element 200, in accordance with the present disclosure. Ring shaped TMR element 200 includes first and second ferromagnetic layers (FMs) 201 and 202 (indicated as FM1 and FM2) separated by insulative layer (IL) 203. First and second contacts (e.g., contact layers) 204 and 205 can be provided for ferromagnetic layers (FM1) 201 and (FM2) 202, respectively. The contact layers 204-204 can include more complex structures/arrangements, such as pinning layers. Layers 201-205 can form a stacked structure 206 supported by substrate 207, as shown. Stacked structure 206 can have a (circular) cylindrical shape, which facilitates improved/increased linearity of device signal response in operation. Stacked structure 206 can have an outer diameter D1 and an inner diameter D2, with the difference between the two diameters corresponding to a thickness of structure 206, e.g., as indicated.

The first and second ferromagnetic layers 201, 202 with the insulative layer 203 represent the magnetic tunnel junction (MTJ) of the element 200. Tunneling magnetoresistance (TMR) occurs in the magnetic tunnel junction (MTJ) during device (element 200) operation. First and second ferromagnetic layers 201 (FM1) and 202 (FM2) are separated by a thin insulative layer (IL) 203, such as MgO. The insulative layer 203 is preferably relatively thin, e.g., on the order of a few nanometers, so as to benefit from and facilitate a quantum mechanical phenomenon allowing electrons to “tunnel” from one of the ferromagnetic layers to the other. Insulative layer (IL) 203 can be or include any suitable material, e.g., MgO and/or the like. The dimensions of the TMR (MTJ) elements can be selected as desired. For example, in some embodiments, a width of a TMR (MTJ) ring structure may be between about 1.0 micron and about 2.0 microns; in some embodiments, a radial thickness of a TMR (MTJ) ring structure may be between about 150 nm and about 500 nm. Other dimensions may of course be used/practiced within the scope of the present disclosure.

The direction of the two magnetizations of the ferromagnetic layers (films) FM1 201, FM2 202 can be switched individually by an external magnetic field. If the magnetizations are in a parallel orientation it is more likely that electrons will tunnel through the insulating film IL than if they are in the oppositional (antiparallel) orientation. Consequently, such a junction can be switched between two states of electrical resistance, one with low resistance and one with high resistance.

The directions of the magnetizations of FM1 201 and FM2 202 do not necessarily have to be switched: if the external field angle is neither parallel nor anti-parallel then the resulting magnetization of the free layer changes as the composite angle between the external field and the reference layer. The conductance variation is proportional to the cosine of such composite angle which makes TMR elements useful for angle sensing applications.

As is known for MTJs, electrons with certain spin orientation (“spin-up” or “spin-down”) can tunnel from one ferromagnetic layer to another ferromagnetic layer through the non-conductive thin insulating layer if there are available free states with the same spin orientation. In case of the parallel state, the majority spin (“spin-up”) electrons and minority spin (“spin-down”) electrons can tunnel to the second ferromagnetic layer and fill majority (“up”) and minority (“down”) states, respectively. This will result in large conductance and corresponds to the low resistive state. In case of the anti-parallel state, the majority spin (“spin-down”) electrons and minority spin (“spin-up”) electrons from first ferromagnetic layer fill the minority (“down”) and majority (“up”) states in the second ferromagnetic layer, respectively. This will result in the low conductance and corresponds to the high resistive state. Tunneling magnetoresistance is described in J. Mathon, Theory of Tunneling Magnetoresistance, 76 PHASE TRANSITIONS 491-500 (2003), which is incorporated herein in its entirety by reference.

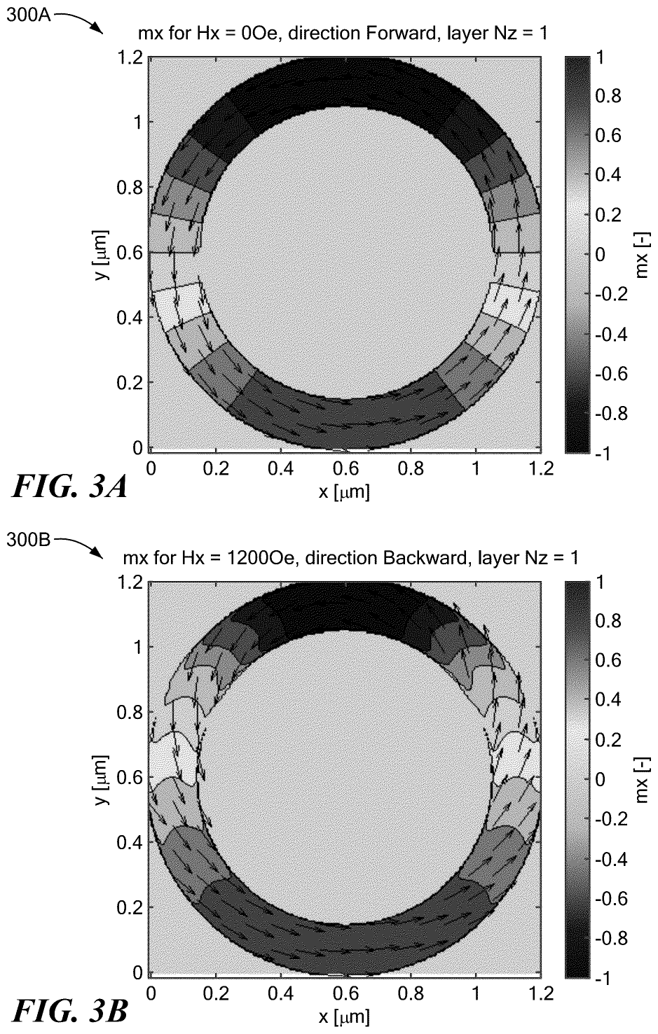

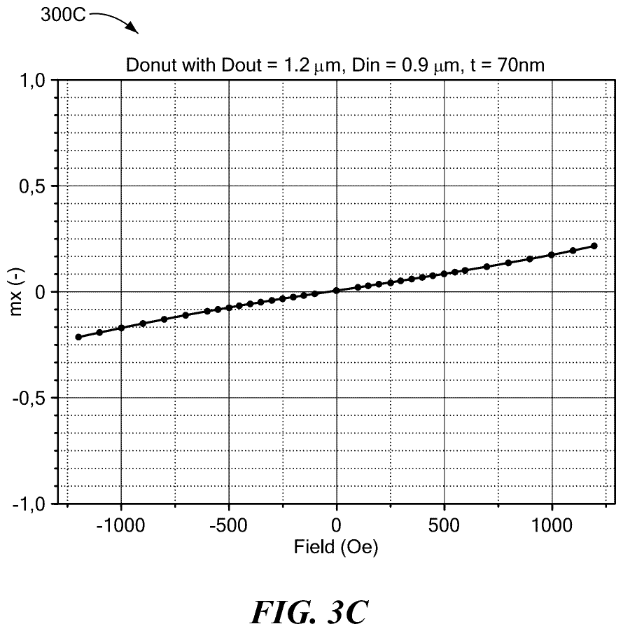

FIGS. 3A-3C are diagrams 300A-300C showing linearity vs. field strength and magnetizations for two different field strengths, respectively, for an example ring shaped TMR element, in accordance with the present disclosure. The example TMR element had a ring shape with an outer diameter of 1.2 micron, an inner diameter of 0.9 micron and a height of 70 nm. Note: all magnetization plots show simulations.

FIG. 3A shows plot 300A illustrating a linear magnetization over a range of field strength for the ring shaped TMR element having an outer diameter of 1.2 micron (1200 nm) and an inner diameter of 0.9 micron (900 nm) and a thickness (stack height) of 70 nm.

As shown in FIG. 3B, linearization is obtained by shape anisotropy as the magnetization tends to stay parallel to the edges

As shown in FIG. 3C, an embodiment having a width of 0.15 μm was shown to be unsaturated under external field of 1200 Oe.

For embodiments of the present disclosure, multiple ring shaped TMR elements can overlap to reduce the transducer footprint. The grouped elements will then be equivalent to single elements that are electrically connected in parallel.

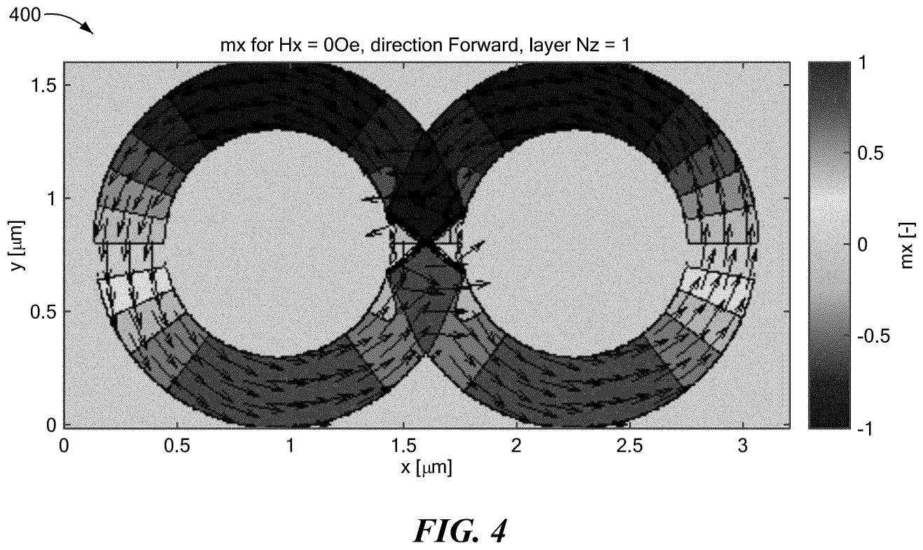

FIG. 4 is a plot 400 showing modeled magnetization for an example double-ring shaped TMR element, in accordance with the present disclosure. The double-ring structure had an x-dimension of 3.0 micron, a y-dimension of 1.5 micron, and a z-dimension (height) of 70 nm. The example shown in FIG. 4 includes a grouping of two ring elements combined; the same or similar method can be used for higher number of elements.

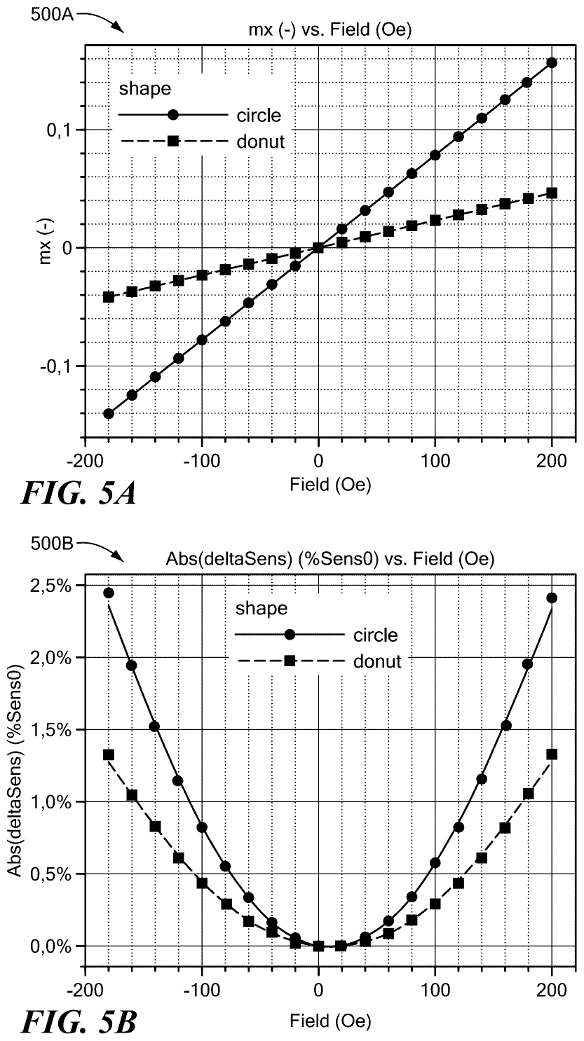

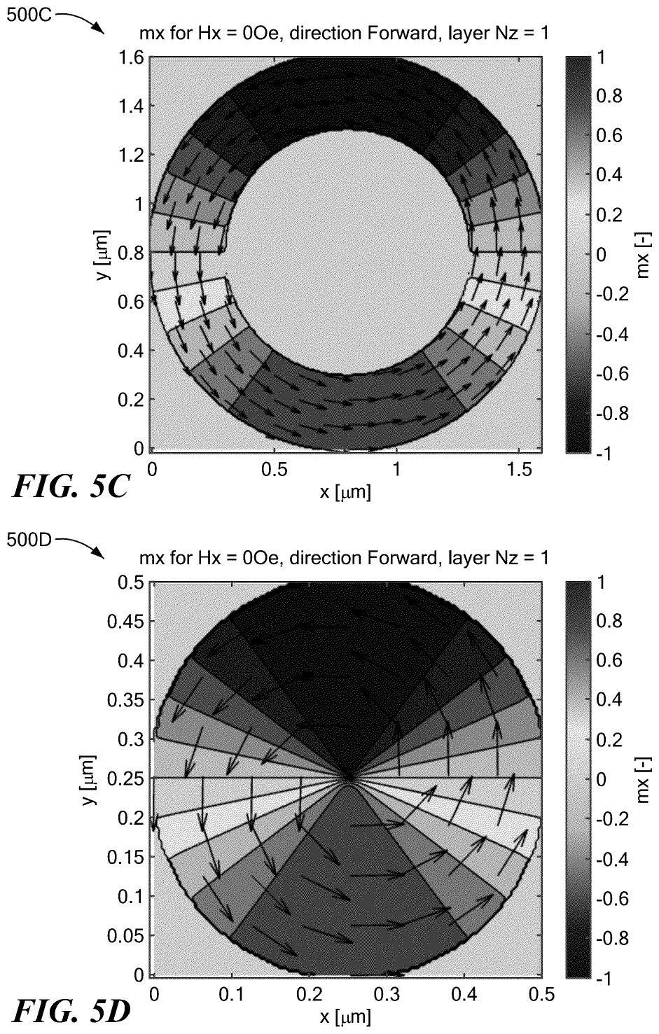

FIGS. 5A-5B are graphs 500A-500B showing magnetization performance for an example ring shaped TMR element in accordance the present disclosure compared to a prior art disc shaped TMR element; FIGS. 5C-5D show magnetizations for the example ring shaped TMR element 500C and the prior art disc shaped element 500D, respectively. The ring shaped embodiment 500C modeled in FIGS. 5A and 5B (and shown in FIG. 5C) had an outer diameter of 1.6 micron, an inner diameter of 1.0 micron, and a thickness of 70 nm. The circular disc shaped TMR element modeled in FIGS. 5A and 5B (and shown in FIG. 5D) had an outer diameter of 0.5 micron and a thickness of 70 nm.

FIG. 5A shows magnetic moment (proportional to device conductance) while FIG. 5B shows device sensitivity variation.

As shown in FIGS. 5A-5B, the sensitivity of ring shaped TMR elements is somewhat reduced compared to typical vortex TMR element with circle shape but the ring shaped element provided improvement of the linearity.

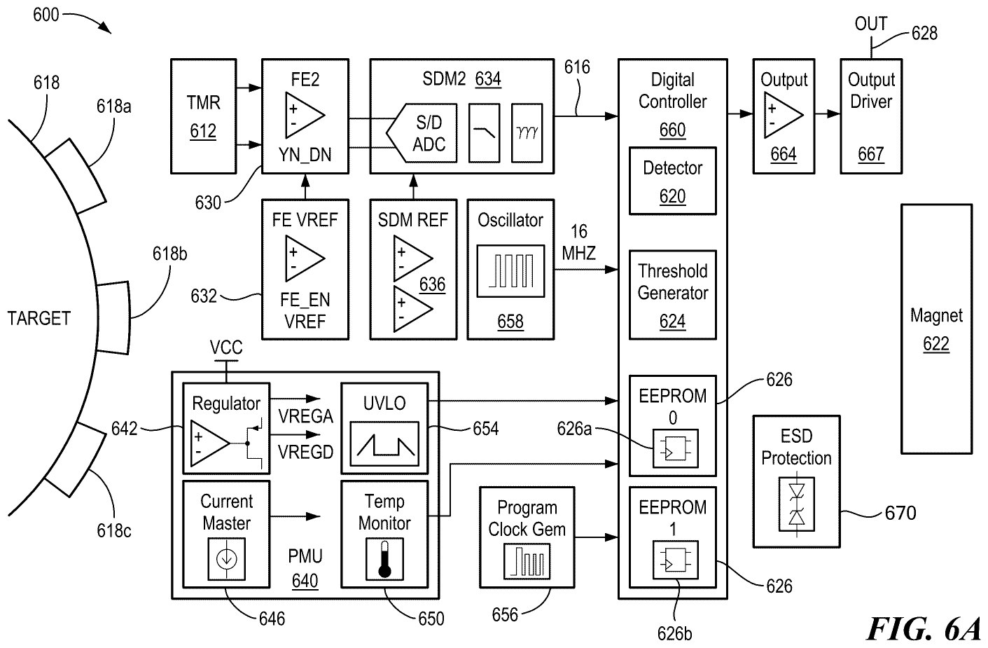

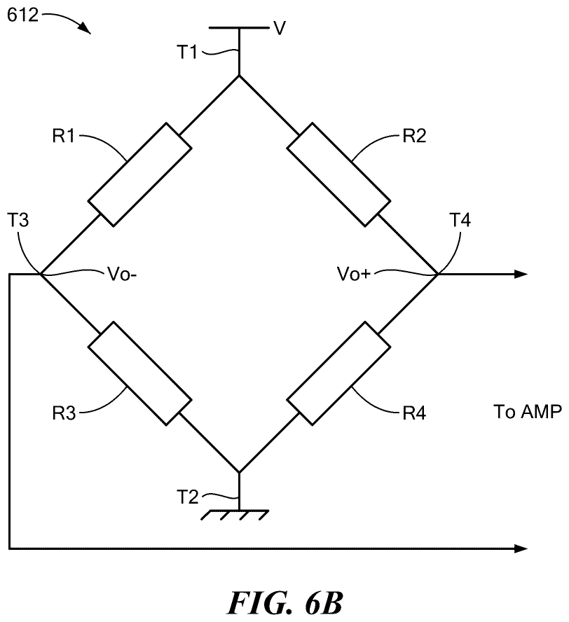

FIGS. 6A-6B show a circuit diagram for an example magnetic field sensor 600 utilizing ring shaped TMR elements, in accordance with the present disclosure. Magnetic field sensor 600 includes at least one magnetic field sensing element 612 that includes one or more ring shaped TMR elements in accordance with the present disclosure. The sensor 600 is configured to generate a magnetic field signal 616 indicative of a magnetic field associated with a magnetic target 618 (which may have multiple components or parts, e.g., 618a-c) and a detector 620 responsive to the magnetic field signal and to a threshold level from a threshold generator 624 to generate a sensor output signal 628 containing transitions associated with features of the target 618 in response to the magnetic field signal crossing the threshold level.

The target 618 can have a variety of forms, including, but not limited to a gear having gear teeth 618a-618c or a ring magnet having one or more pole pairs. Also, linear arrangements of ferromagnetic objects that move linearly are possible. In the example embedment of FIG. 6, magnetic field sensor 600 may take the form of a rotation detector to detect passing gear teeth, for example, gear teeth 618a-618c of a ferromagnetic gear—or, more generally, target object 618. A permanent magnet 622 can be placed at a variety of positions proximate to the gear 618, resulting in fluctuations of a magnetic field proximate to the gear as the gear rotates in a so-called “back-bias” arrangement.

Features of the target 618 are spaced from the TMR sensing elements 612 by an airgap. Although intended to be fixed once the sensor 600 is in place in a particular application, the airgap can vary for a variety of reasons. A difference between angles of the transitions of the sensor output signal 628 and locations of the associated features 618a-618c of the target 618 may be referred to as a “hard offset.”

The one or more TMR sensing elements 612 can take a variety of forms as may be arranged in one or more bridge (or other types of) configurations in order to generate one or more single-ended or differential signals indicative of the sensed magnetic field. A front-end amplifier 630 can be used to process the magnetic field sensing element output signal to generate a further signal for coupling to an analog-to-digital converter (ADC) 634 as may include one or more filters, such as a low pass filter and/or notch filter, and as may take the form of, e.g., a sigma-delta modulator to generate a digital magnetic field signal 616. Features of the magnetic field signal processing can include a front-end reference 632 and a sigma delta reference 636.

Sensor 600 includes a power management unit (PMU) 640 as may contain various circuitry to perform power management functions. For example, a regulator 642 can output a regulated voltage for powering analog circuitry of the sensor (VREGA) and/or a regulated voltage for powering digital circuitry of the sensor (VREGD). A bias current source 646, a temperature monitor 650 and an undervoltage lockout 654 can monitor current, temperature, and voltage levels and provide associated status signals to a digital controller 660. A clock generation element 656 and an oscillator 658 are coupled to the digital controller 660.

Digital controller 660 processes the magnetic field signal 616 to determine the speed, position, and/or direction of movement, such as rotation of target 618 and outputs one or more digital signals to an output protocol module 664. More particularly, controller 660 determines the speed, position, and/or direction of target 618 based on the magnetic field signal 616 and can combine this information with fault information in some embodiments to generate the sensor output signal 628 in various formats. The output of module 664 is fed to an output driver 667 that provides the sensor output signal 628 in various formats, such as a so-called two-wire format in which the output signal is provided in the form of current pulses on the power connection to the sensor or a three-wire format in which the output signal is provided at a separate dedicated output connection. Formats of the output signal 628 can include variety of formats, for example a pulse-width modulated (PWM) signal format, a Single Edge Nibble Transmission (SENT) format, a Serial Peripheral Interface (SPI) format, a Local Interconnect Network (LIN) format, a CAN (Controller Area Network) format, an Inter-Integrated Circuit (I2C) format, or other similar signal formats. Sensor 10 can further include electrostatic discharge (ESD) protection 670.

The digital controller 660 includes detector 620, threshold generator 624, and memory 626 such as EEPROMs 626a, 626b. Memory 626 can be used to store values for various sensor functionality including storing function coefficients for use by the threshold generator 624 in generating the adaptive threshold levels for use by detector 620.

Detector 620 is coupled to receive the threshold level thus generated and the magnetic field signal 616 and compare the received levels to generate a binary, two-state, detector output signal that has transitions when the signal 16 crosses the threshold level. Movement speed of the target 618 can be detected in accordance with the frequency of the binary signal.

It should be appreciated that a direction of rotation of the target 618 may be determined in embodiments containing multiple sensing elements 612 configured to generate phase separated magnetic field signals (as are sometimes referred to as channel signals), in which case the direction of rotation can be determined based on a relative phase or relative time difference (e.g., lag or lead) of a particular edge transition of detector output signals associated with the phase separated magnetic field signals.

A person of ordinary skill in the art should understood that embodiments of ring shaped TMR-based sensing elements in accordance with the present disclosure can be useful in a wide variety of magnetic sensor applications. While an example sensor is shown and described above, any practical magnetic sensor in which TMR sensing elements are desirable can be provided. For example, TMR sensing elements are useful in many magnetic position and angle sensors that require high resolution.

As noted above, TMR-based sensors in accordance with the present disclosure can utilize TMR elements as resistors arranged in one or more bridge configurations, e.g., a Wheatstone bridge. Such bridge configurations or arrangements can offer, e.g., a fully differential voltage output which, among other things, is decoupled from common mode variations and provides a large rejection to power supply noise.

The lower portion of FIG. 6 presents an enlarged view of example TMR sensing element 612, which is shown as having a bridge configuration with first ring shaped TMR element (represented by resistor R1), a second ring shaped TMR element (represented by resistor R2), a third ring shaped TMR element (represented by resistor R3), and a fourth ring shaped TMR element (represented by resistor R4) coupled in a bridge configuration. A first terminal T1 is coupled to a voltage supply and a second terminal T2 is coupled to ground (or other potential). A third terminal T3 provides a first differential output signal Vo− and a fourth terminal T4 provides a second differential output signal Vo+. The differential output Vo+, Vo− of the bridge can be provided to an amplifier (AMP) or other circuitry for processing of the output of the magnetic field sensing elements.

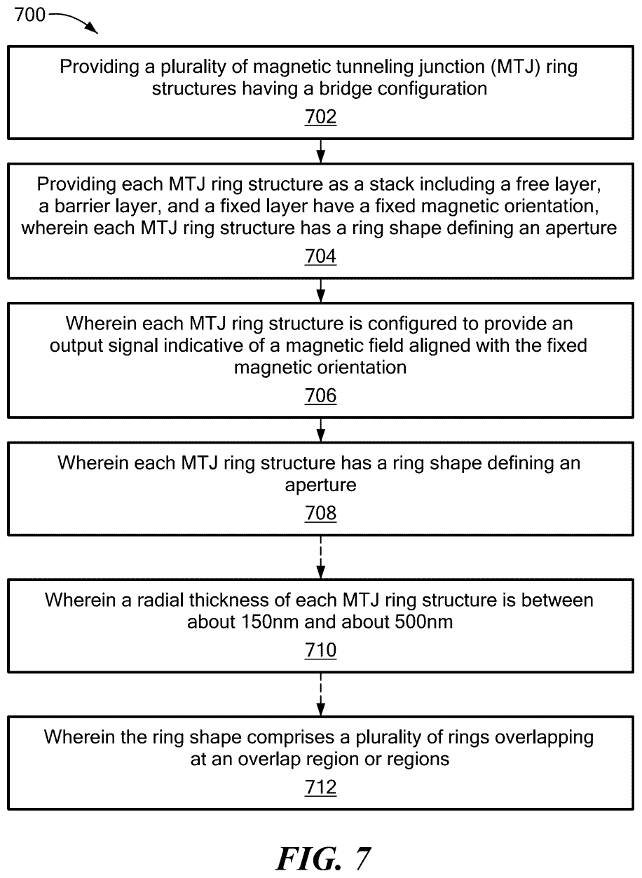

FIG. 7 shows steps in an example method 700 of making a TMR sensor utilizing a ring shape TMR element, in accordance with the present disclosure. Method 700 can include providing a plurality of magnetic tunneling junction (MTJ) ring structures having a bridge configuration, as described at 702. Each MTJ ring structure can be provided as a stack including a free layer, a barrier layer, and a fixed layer have a fixed magnetic orientation, where each MTJ ring structure has a ring shape defining an aperture, as described at 704. Each MTJ ring structure can be configured to provide an output signal indicative of a magnetic field aligned with the fixed magnetic orientation, as described at 706. Each MTJ ring structure can have a ring shape defining an aperture, as described at 708. In some embodiments, a radial thickness of each MTJ ring structure can be between about 150 nm and about 500 nm, as described at 710. In some embodiments, the ring shape can include a plurality of rings overlapping at an overlap region or regions, as described at 712. For example, two rings may overlap in a figure-eight configuration, etc.; in other embodiments, multiple rings may overlap in a structure that has multiple overlap (overlapping) regions.

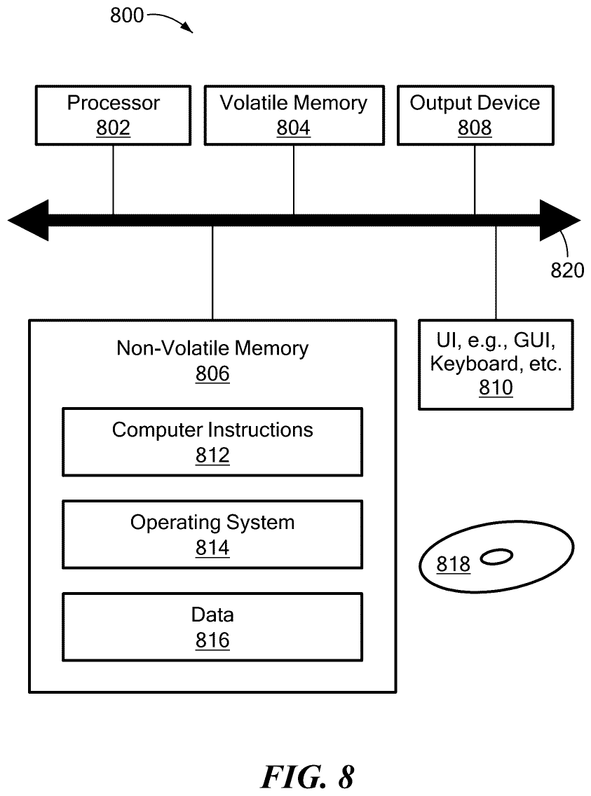

FIG. 8 is a block diagram of an example computer system 800 operative to perform processing, in accordance with the present disclosure, e.g., computation (calculation) of an AC current based on an output signal or signals received from a current sensor. Computer system 800 can perform all or at least a portion of the processing, e.g., steps in algorithms and methods, described herein. The computer system 800 includes a processor 802, a volatile memory 804, a non-volatile memory 806 (e.g., hard disk, etc.), an output device 808 and a user input or interface (UI) 810, e.g., graphical user interface (GUI), a mouse, a keyboard, a display, and/or any common user interface, etc. The non-volatile memory (non-transitory storage medium) 806 stores computer instructions 812 (a.k.a., machine-readable instructions or computer-readable instructions) such as software (computer program product), an operating system 814 and data 816. In some examples/embodiments, the computer instructions 812 can be executed by the processor 802 out of (from) volatile memory 804. In some examples/embodiments, an article 818 (e.g., a storage device or medium such as a hard disk, an optical disc, magnetic storage tape, optical storage tape, flash drive, etc.) includes or stores the non-transitory computer-readable instructions. Bus 820 is also shown. In some embodiments, one or more components of system 800 can be disposed on or connected to one or more integrated circuits on one or more semiconductor die.

Processing may be implemented in hardware, software, or a combination of the two. Processing may be implemented in computer programs (e.g., software applications) executed on programmable computers/machines that each includes a processor, a storage medium or other article of manufacture that is readable by the processor (including volatile and non-volatile memory and/or storage elements), and optionally at least one input device, and one or more output devices. Program code may be applied to data entered using an input device or input connection (e.g., a port or bus) to perform processing and to generate output information.

The system 800 can perform processing, at least in part, via a computer program product or software application, (e.g., in a machine-readable storage device), for execution by, or to control the operation of, data processing apparatus (e.g., a programmable processor, a computer, or multiple computers). Each such program may be implemented in a high-level procedural or object-oriented programming language to communicate with a computer system. The programs may be implemented in assembly or machine language. The language may be a compiled or an interpreted language and it may be deployed in any form, including as a stand-alone program or as a module, component, subroutine, or other unit suitable for use in a computing environment. A computer program may be deployed to be executed on one computer or on multiple computers at one site or distributed across multiple sites and interconnected by a communication network. A computer program may be stored on a storage medium or device (e.g., CD-ROM, hard disk, or magnetic diskette) that is readable by a general or special purpose programmable computer for configuring and operating the computer when the storage medium or device is read by the computer. Processing may also be implemented as a machine-readable storage medium, configured with a computer program, where upon execution, instructions in the computer program cause the computer to operate. Further, the terms “computer” or “computer system” may include reference to plural like terms, unless expressly stated otherwise.

Processing may be performed by one or more programmable processors executing one or more computer programs to perform the functions of the system. All or part of the system may be implemented as special purpose logic circuitry, e.g., an FPGA (field programmable gate array) and/or an ASIC (application-specific integrated circuit). In some examples, digital logic circuitry, e.g., one or more FPGAs, can be operative as one or more processors as described herein.

Accordingly, embodiments of the inventive subject matter can afford various benefits relative to prior art techniques. For example, embodiments and examples of the present disclosure can provide, enable and/or facilitate TMR elements with ring shapes that provide improved/increased linearity compared to prior techniques and structure.

Various embodiments of the concepts, systems, devices, structures, and techniques sought to be protected are described above with reference to the related drawings. Alternative embodiments can be devised without departing from the scope of the concepts, systems, devices, structures, and techniques described.

It is noted that various connections and positional relationships (e.g., over, below, adjacent, etc.) may be used to describe elements and components in the description and drawings. These connections and/or positional relationships, unless specified otherwise, can be direct or indirect, and the described concepts, systems, devices, structures, and techniques are not intended to be limiting in this respect. Accordingly, a coupling of entities can refer to either a direct or an indirect coupling, and a positional relationship between entities can be a direct or indirect positional relationship.

As an example of an indirect positional relationship, positioning element “A” over element “B” can include situations in which one or more intermediate elements (e.g., element “C”) is between elements “A” and elements “B” as long as the relevant characteristics and functionalities of elements “A” and “B” are not substantially changed by the intermediate element(s).

Also, the following definitions and abbreviations are to be used for the interpretation of the claims and the specification. The terms “comprise,” “comprises,” “comprising,” “include,” “includes,” “including,” “has,” “having,” “contains” or “containing,” or any other variation are intended to cover a non-exclusive inclusion. For example, an apparatus, a method, a composition, a mixture, or an article, which includes a list of elements is not necessarily limited to only those elements but can include other elements not expressly listed or inherent to such apparatus, method, composition, mixture, or article.

Additionally, the term “exemplary” means “serving as an example, instance, or illustration. Any embodiment or design described as “exemplary” is not necessarily to be construed as preferred or advantageous over other embodiments or designs. The terms “one or more” and “at least one” indicate any integer number greater than or equal to one, i.e., one, two, three, four, etc.; though, where context admits, each of those terms may refer to a fractional number greater than one. The term “plurality” indicates any whole or fractional number greater than one. The term “connection” can include an indirect “connection”and a direct “connection”.

References in the specification to “embodiments,” “one embodiment, “an embodiment,” “an example embodiment,” “an example,” “an instance,” “an aspect,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it may affect such feature, structure, or characteristic in other embodiments whether explicitly described or not.

Relative or positional terms including, but not limited to, the terms “upper,” “lower,” “right,” “left,” “vertical,” “horizontal, ”top,“ ”bottom,“ and derivatives of those terms relate to the described structures and methods as oriented in the drawing figures. The terms ”overlying,“ ”atop,“ ”on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements.

Use of ordinal terms such as “first,” “second,” “third,” etc., in the claims to modify a claim element does not by itself connote any priority, precedence, or order of one claim element over another, or a temporal order in which acts of a method are performed but are used merely as labels to distinguish one claim element having a certain name from another element having a same name (but for use of the ordinal term) to distinguish the claim elements.

The terms “approximately” and “about” may be used to mean within ±20% of a target (or nominal) value in some embodiments, within plus or minus (±) 10% of a target value in some embodiments, within ±5% of a target value in some embodiments, and yet within ±2% of a target value in some embodiments. The terms “approximately” and “about” may include the target value. The term “substantially equal” may be used to refer to values that are within ±20% of one another in some embodiments, within ±10% of one another in some embodiments, within ±5% of one another in some embodiments, and yet within ±2% of one another in some embodiments.

The term “substantially” may be used to refer to values that are within ±20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

The disclosed subject matter is not limited in its application to the details of construction and to the arrangements of the components set forth in the following description or illustrated in the drawings. The disclosed subject matter is capable of other embodiments and of being practiced and carried out in various ways.

Also, the phraseology and terminology used in this patent are for the purpose of description and should not be regarded as limiting. As such, the conception upon which this disclosure is based may readily be utilized as a basis for the designing of other structures, methods, and systems for carrying out the several purposes of the disclosed subject matter. Therefore, the claims should be regarded as including such equivalent constructions as far as they do not depart from the spirit and scope of the disclosed subject matter.

Although the disclosed subject matter has been described and illustrated in the foregoing exemplary embodiments, the present disclosure has been made only by way of example. Thus, numerous changes in the details of implementation of the disclosed subject matter may be made without departing from the spirit and scope of the disclosed subject matter.

Accordingly, the scope of this patent should not be limited to the described implementations but rather should be limited only by the spirit and scope of the following claims.

All publications and references cited in this patent are expressly incorporated by reference in their entirety.

What is claimed is:

1. A tunneling magnetoresistance (TMR) sensor comprising:
a plurality of magnetic tunneling junction (MTJ) ring structures having a bridge configuration and configured to provide a bridge output signal;
wherein each MTJ ring structure includes a stack including a free layer, a barrier layer, and a fixed layer have a fixed magnetic orientation, wherein each MTJ ring structure is configured to provide an output signal indicative of a magnetic field aligned with the fixed magnetic orientation, and wherein each MTJ ring structure has a ring shape defining an aperture; and
output circuitry configured to receive the bridge output signal and provide signal conditioning of the output signal.

2. The TMR sensor of claim 1, wherein the bridge configuration comprises a Wheatstone bridge.

3. The TMR sensor of claim 1, wherein the bridge configuration comprise a half-bridge.

4. The TMR sensor of claim 1, wherein a width of each MTJ ring structure is between about 1.0 micron and about 2.0 microns.

5. The TMR sensor of claim 1, wherein a radial thickness of each MTJ ring structure is between about 150 nm and about 500 nm.

6. The TMR sensor of claim 1, wherein the ring shape comprises a plurality of rings overlapping at one or more overlap regions.

7. The TMR sensor of claim 6, wherein the plurality of rings comprises two rings.

8. The TMR sensor of claim 7, wherein the free layer comprises cobalt-iron-boron.

9. The TMR sensor of claim 7, wherein the fixed layer comprises cobalt-iron or cobalt-iron-boron.

10. The TMR sensor of claim 1, wherein the TMR sensor is configured as a differential sensor.

11. The TMR sensor of claim 1, wherein the TMR sensor is configured as an angle sensor.

12. A magnetic tunneling junction (MTJ) ring element comprising:
a free layer of ferromagnetic material;
a barrier layer disposed adjacent the free layer;
a fixed layer of ferromagnetic material disposed adjacent the barrier layer and having a fixed magnetic orientation;
a first conductive element connected to the free layer; and
a second conductive element connected to the fixed layer;
wherein the MTJ ring element is configured to produce an output signal indicative of a presence of a magnetic field aligned fixed magnetic orientation of the fixed layer, and wherein the MTJ ring element is configured as a ring shape defining an aperture.

13. The MTJ ring element of claim 12, wherein a width of the MTJ ring element is between about 1.0 micron and about 2.0 microns.

14. The MTJ element of claim 12, wherein a radial thickness of the MTJ ring element is between about 150 nm and about 500 nm.

15. The MTJ element of claim 12, wherein the ring shape comprises a plurality of rings overlapping at one or more overlap regions.

16. The MTJ element of claim 15, wherein the plurality of rings comprises two rings.

17. The MTJ element of claim 12, wherein the free layer comprises cobalt-iron-boron.

18. The MTJ element of claim 12, wherein the fixed layer comprises cobalt-iron or cobalt-iron-boron.

19. A method of making a TMR sensor having ring elements, the method comprising:
providing a plurality of magnetic tunneling junction (MTJ) ring structures having a bridge configuration;
wherein each MTJ ring structure includes a stack including a free layer, a barrier layer, and a fixed layer have a fixed magnetic orientation, wherein each MTJ ring structure is configured to provide an output signal indicative of a magnetic field aligned with the fixed magnetic orientation, and wherein each MTJ ring structure has a ring shape defining an aperture; and
providing output circuitry configured to receive the output signal and provide signal conditioning of the output signal.

20. The method of claim 19, wherein the barrier layer comprises an oxide.

21. The method of claim 20, wherein the oxide comprises aluminum oxide or magnesium oxide.

22. The method of claim 19, wherein the free layer comprises cobalt-iron-boron.

23. The method of claim 19, wherein the fixed layer comprises cobalt-iron or cobalt-iron-boron.

24. The method of claim 19, wherein a width of each MTJ ring structure is between about 1.0 micron and about 2.0 microns.

25. The method of claim 19, wherein a radial thickness of each MTJ ring structure is between about 150 nm and about 500 nm.

26. The method of claim 19, wherein the ring shape of each MTJ ring structure comprises a plurality of rings overlapping at one or more overlap regions.

27. The method of claim 26, wherein the plurality of rings comprises two rings.
